(19) United States
(12) Patent Application Publication
(10) Pub. No.: US 2024/0421263 A1
(43) Pub. Date: Dec. 19, 2024

(54) LED CHIP AND LED CHIP PREPARATION METHOD

(71) Applicant: XIAMEN CHANGELIGHT CO., LTD., Xiamen (CN)

(72) Inventors: Xingen WU, Xiamen (CN); Yingce LIU, Xiamen (CN); Wei LIU, Xiamen (CN); Rui WANG, Xiamen (CN); Fengjie LIN, Xiamen (CN); Hengping CUI, Xiamen (CN); Yumei CAI, Xiamen (CN); Haifang CAI, Xiamen (CN)

(73) Assignee: XIAMEN CHANGELIGHT CO., LTD., Xiamen (CN)

(21) Appl. No.: 18/816,600

(22) Filed: Aug. 27, 2024

Related U.S. Application Data
(63) Continuation of application No. PCT/CN2022/123210, filed on Sep. 30, 2022.

(30) Foreign Application Priority Data
Mar. 30, 2022 (CN) 202210327434.7
Mar. 30, 2022 (CN) 202220719631.9

(51) Int. Cl. H01L 33/46; H01L 33/38

(52) U.S. Cl. CPC H01L 33/46; H01L 33/38; H01L 2933/0016; H01L 2933/0025

(57) ABSTRACT

An LED chip includes: an epitaxial stack, including a recess and a mesa; an isolating layer, covering the epitaxial stack and exposing a portion of a surface of the recess to form a recess exposed portion. The isolating layer includes at least one through hole along a surface of the mesa. A current spreading layer is stacked on a side surface of the isolating layer, where the side surface is located away from the mesa, and the current spreading layer is embedded in the at least one through hole. A reflective layer covers the current spreading layer and the isolating layer, where the reflective layer exposes the recess exposed portion and includes an electrode hole, the electrode hole exposes a portion of the current spreading layer.

### CROSS-REFERENCE TO RELATED APPLICATIONS

This application is a continuation of PCT application No. PCT/CN2022/123210, filed on Sep. 30, 2022, which claims priority to the Chinese patent application No. 202210327434.7, filed on Mar. 30, 2022, entitled “An LED chip and its preparation method”, and Chinese patent application No. 202220719631.9, filed on Mar. 30, 2022, entitled “an LED chip and its preparation method,” the entire disclosures of which are incorporated herein by reference.

### BACKGROUND

With the rapid development of LED technology and the gradual improvement of LED luminous efficiency, the application of LED is more and more extensive, and people are more and more concerned about the development prospect of LED in the display screen. LED chip, as the core component of LED light, has the function of converting electrical energy into light energy, specifically, by including an epitaxial wafer, and an N-type electrode and a P-type electrode respectively set on the epitaxial wafer. The epitaxial wafer includes a P-type semiconductor layer, an N-type semiconductor layer, and an active layer located between the N-type semiconductor layer and the P-type semiconductor layer, and when there is a current passing through the LED chip, the holes in the P-type semiconductor and electrons in the N-type semiconductor will move toward the active layer and be compounded in the active layer, causing the LED chip to emit light.

Currently, the mainstream Mini LED chips on the market use a current of less than 0.5 mA, and some even use a current between 10 and 20 μA. As the current used decreases, the luminous efficiency needs to be improved. FIG. 1 lists the relationship between the luminous efficiency (vertical axis) and current density (horizontal axis) of a 4 mil*8 mil size LED chip. It can be found that, from the perspective of luminous efficiency and current density, the optimal luminous efficiency of an LED chip of this size is 4˜6 A/cm2. Assume that the current used is 20 μA. Then the optimal light-emitting area is calculated to be 333 μm2 to 500 μm2; at the same time, as shown in FIG. 2, it is usually necessary to etch the current spreading layer 6 to form the electrode hole 15 in product design; however, for small-size LEDs, due to their unit area Too small, thin, photolithography diffraction, and poor etching depth make it difficult to control the ITO area, resulting in ITO pattern abnormalities, as shown in FIG. 3. In addition, as ITO is a transparent conductive layer, it is usually necessary to design a current spreading electrode to connect to the ITO surface to form a current loop. However, the reflectivity of the current spreading electrode can only reach about 70% at most, and its ability to reflect light in the luminescent area is weak. Moreover, the current accumulates directly under the current spreading electrode, and electrostatic breakdown is prone to occur.

### SUMMARY

The present disclosure relates to the field of light-emitting diodes, and in particular relates to an LED chip and its preparation method. Embodiments of the present disclosure is to provide an LED chip and a preparation method thereof to achieve precise control of the light-emitting area and improve the antistatic ability of the LED chip.

According to a first aspect of the present disclosure, some embodiments provide an LED chip. The LED chip includes: a substrate; an epitaxial stack, provided on a surface of the substrate, including a recess and a mesa; an isolating layer, covering the epitaxial stack and exposing a portion of a surface of the recess to form a recess exposed portion, wherein the isolating layer includes at least one through hole along a surface of the mesa; a current spreading layer, stacked on a side surface of the isolating layer, wherein the side surface is located away from the mesa, and the current spreading layer is embedded in the at least one through hole to contact with the epitaxial stack; a reflective layer, covering the current spreading layer and the isolating layer, wherein the reflective layer exposes the recess exposed portion and includes an electrode hole, the electrode hole exposes a portion of the current spreading layer; a first electrode, stacked on the recess exposed portion and extending upward to a surface of the reflective layer; and a second electrode, stacked on the electrode hole and extending upward to the surface of the reflective layer.

According to a second aspect of the present disclosure, some embodiments provide an LED chip preparation method. The LED chip preparation method includes: providing a substrate; stacking an epitaxial stack on a surface of the substrate; etching a local area of the epitaxial stack to form a recess and a mesa; etching an edge of the epitaxial stack to form a substrate exposed portion; growing an isolating layer which covers the epitaxial stack and exposes a portion of a surface of the recess to form a recess exposed portion, wherein the isolating layer includes at least one through hole along a surface of the mesa; depositing a current spreading layer which is stacked on a side surface of the isolating layer, wherein the side surface is located away from the mesa, and the current spreading layer is embedded in the at least one through hole to contact with the epitaxial stack; depositing a reflective layer which covers the current spreading layer and the isolating layer, wherein the reflective layer exposes the recess exposed portion and includes an electrode hole, the electrode hole exposes a portion of the current spreading layer; preparing a first electrode and a second electrode, wherein the first electrode is stacked on the recess exposed portion, the second electrode is stacked in the electrode hole, and the first electrode and the second electrode are disposed away from each other.

### BRIEF DESCRIPTION OF THE DRAWINGS

In order to explain the embodiments of the present disclosure or the technical solutions in the prior art more clearly, the drawings needed to be used in the description of the embodiments or the prior art will be briefly introduced below. The drawings in the following description are only These are embodiments of the present disclosure.

FIG. 1 shows a schematic diagram of the relationship between the luminous efficiency and current density of a 4 mil*8 mil size LED chip in the prior art.

FIG. 2 shows a schematic diagram of a structure of making a current spreading layer on a light-emitting mesa of an LED chip in the prior art.

FIG. 3 is a schematic diagram of the anomalies that occur during the production of the current spreading layer shown in FIG. 2.

FIG. 4 shows a schematic diagram of the structure of the LED chip provided by an embodiment of the present disclosure.

FIGS. 5A to 5I are schematic diagrams of the structures corresponding to the steps of the preparation method of the LED chip provided by an embodiment of the present disclosure.

FIG. 6 is a flowchart illustrating an exemplary process of an LED chip preparation method provided by an embodiment of the present disclosure.

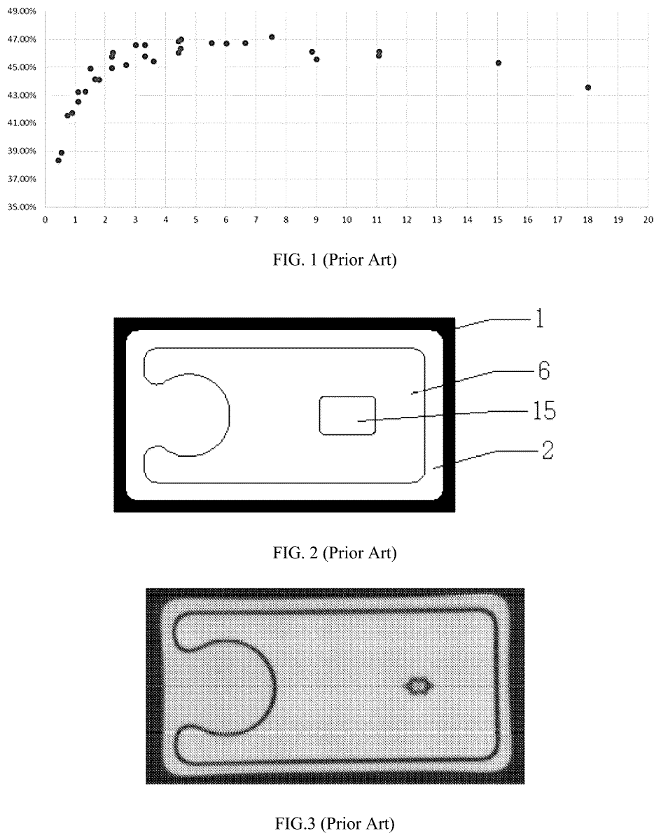

### DETAILED DESCRIPTION

To make the present disclosure clearer, the contents of the present disclosure are further described below in connection with the accompanying drawings. The present disclosure is not limited to this specific embodiment. Based on the embodiment in the present disclosure, all other embodiments obtained by those skilled in the art without making creative labor fall within the scope of protection of the present disclosure.

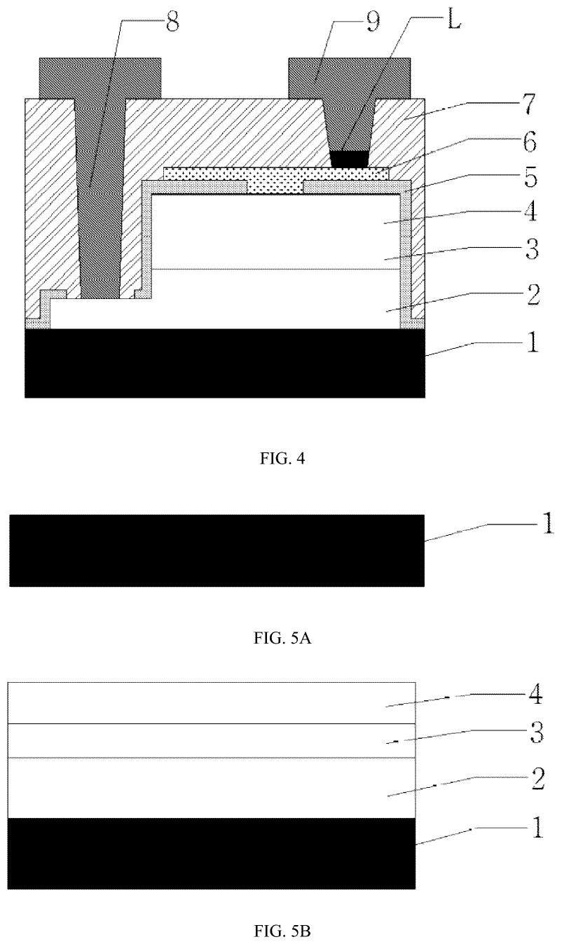

As shown in FIG. 4, some embodiments of the present disclosure provide an LED chip. The LED chip includes: a substrate 1, an epitaxial stack, an isolating layer 5, a current spreading layer 6, a reflective layer 7, a first electrode 8, and a second electrode 9.

The epitaxial stack is provided on the surface of the substrate 1. The epitaxial stack includes a recess 11 and a mesa 10. The isolating layer 5 covers the epitaxial stack and exposing a portion of the surface of the recess 11 to form a recess exposed portion 14. The isolating layer 5 includes at least one through hole 13 along a surface of the mesa 10.

The current spreading layer 6 is stacked on a side surface of the isolating layer 5. The side surface is located away from the mesa 10, and the current spreading layer 6 is embedded in the at least one through hole 13 to contact with the epitaxial stack.

The reflective layer 7 covers the current spreading layer 6 and the isolating layer 5. The reflective layer 7 exposes the recess exposed portion 14 and includes an electrode hole 15, the electrode hole 15 exposes a portion of the current spreading layer 6, and in some embodiments, the center of the electrode hole 15 may not be aligned with the center of the at least one through hole 13.

The first electrode 8 is stacked on the recess exposed portion 14 and extending upward to a surface of the reflective layer 7.

The second electrode 9 is stacked on the electrode hole 15 extending upward to the surface of the reflective layer 7.

In some embodiments, the epitaxial stack includes a first type semiconductor layer 2, an active layer 3, and a second type semiconductor layer 4. The first type semiconductor layer 2, the active layer 3, and the second type semiconductor layer 4 are sequentially stacked in a first direction. A local area of the epitaxial stack is etched to a part of the first type semiconductor layer 2, forming the recess 11 and the mesa 10. The first direction is perpendicular to the substrate 1, and points from the substrate 1 to the epitaxial stack. However, the detailed structure of the epitaxial stack is not limited to the embodiments of the present disclosure.

In some embodiments, the type of the substrate 1 is not limited in this embodiment of the LED chip. For example, the substrate 1 may be, but is not limited to, the sapphire substrate 1, the silicon substrate 1, and the like. Also, the types of the first type semiconductor layer 2, the active layer 3, and the second type semiconductor layer 4 of the epitaxial stack may not be limited in the LED chip of the present embodiment. For example, the first type semiconductor layer 2 may be, but is not limited to, a gallium nitride layer, and accordingly, the second type semiconductor layer 4 may be, but is not limited to, a gallium nitride layer;

In some embodiments, the material of the isolating layer 5 may be, but is not limited to, SiO₂ (silicon dioxide).

In another embodiment of the present disclosure, the total surface area of the at least one through hole 13 is S, and the area of a top surface of the mesa 10 is A, and S≥A/5. The total surface area of the at least one through hole is a sum of at least one projected area of the at least one through hole on the top surface of the mesa.

In another embodiment of the present disclosure, the at least one through hole 13 does not overlap with the electrode hole 15 in orthogonal projections onto the mesa 10.

In another embodiment of the present disclosure, the at least one through hole 13 includes a plurality of sub-through holes and a central through hole, and each of the plurality of sub-through holes is uniformly distributed around the central through hole.

In another embodiment of the present disclosure, the current spreading layer 6 includes a current spreading metal layer L and the electrode hole 15 exposes the current spreading metal layer L to form a connection between the second electrode 9 and the current spreading metal L. The current spreading metal layer L is made of any one or any combination of chromium, nickel, aluminum, titanium, platinum, gold, palladium, silver, or a gold-tin alloy.

In some other embodiments of the present disclosure, further, another current spreading metal layer L is provided in the recess exposed portion 14 and the first electrode 8 is stacked on the surface of the current spreading metal layer L and extends upwardly to the surface of the reflective layer, which is not limited by this embodiment.

In another embodiment of the present disclosure, the current spreading layer 6 is made of any one or any combination of ITO, IZO, IGO, or ZnO.

In another embodiment of the present disclosure, the reflective layer 7 includes a Distributed Bragg Reflector (DBR) reflective layer 7.

In another embodiment of the present disclosure, the isolating layer 5 includes an insulating material.

In another embodiment of the present disclosure, the first electrode 8 and the second electrode 9 is made of any one or any combination of chromium, nickel, aluminum, titanium, platinum, gold, palladium, silver, or a gold-tin alloy, respectively.

In another embodiment of the present disclosure, the epitaxial stack includes at least one substrate exposed portion 12. Both the isolating layer 5 and the reflective layer 7 are stacked to the substrate 1 in a manner by being retained on the at least one substrate exposed portion 12.

In another embodiment of the present disclosure, the at least one substrate exposed portion 12 surrounds a perimeter of the epitaxial stack; and both the isolating layer 5 and the reflective layer 7 are stacked on the substrate 1 in such a manner by being retained in the at least one substrate exposed portion 12 and surrounding the perimeter of the epitaxial stack.

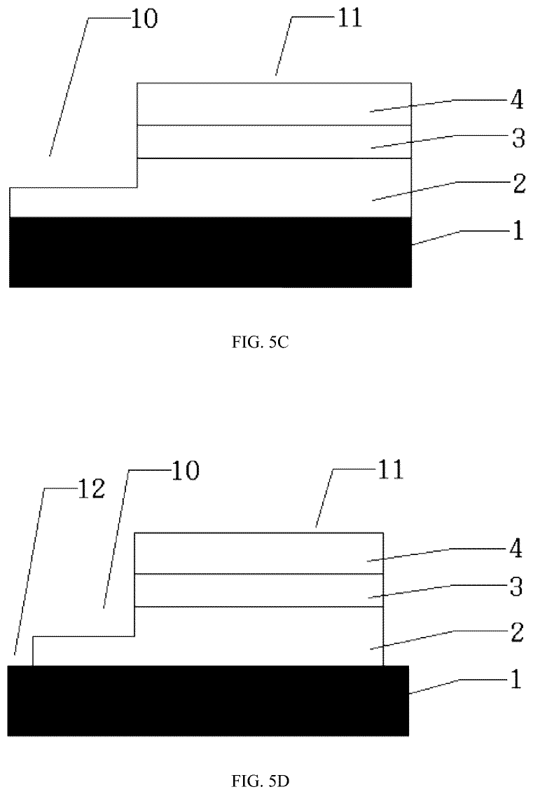

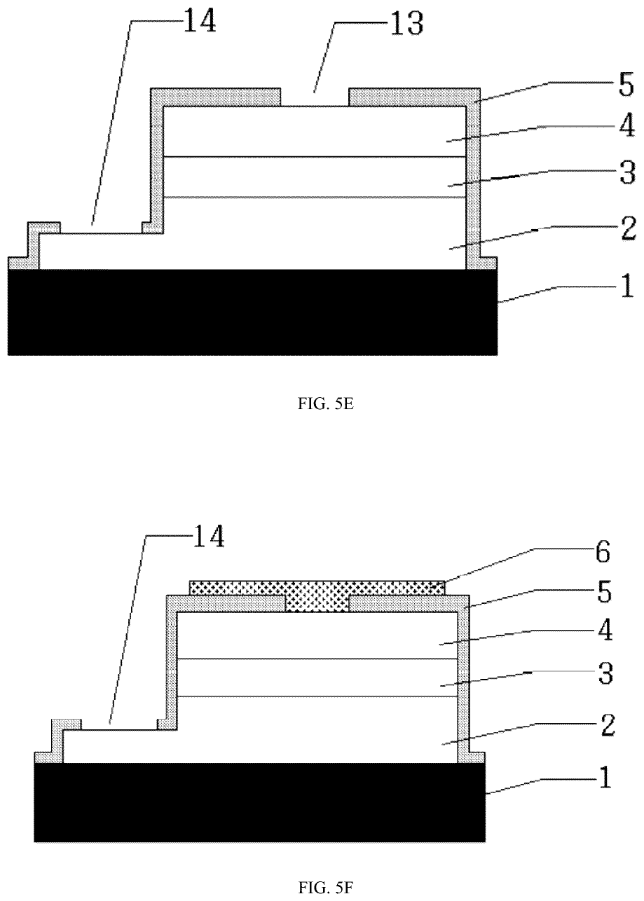

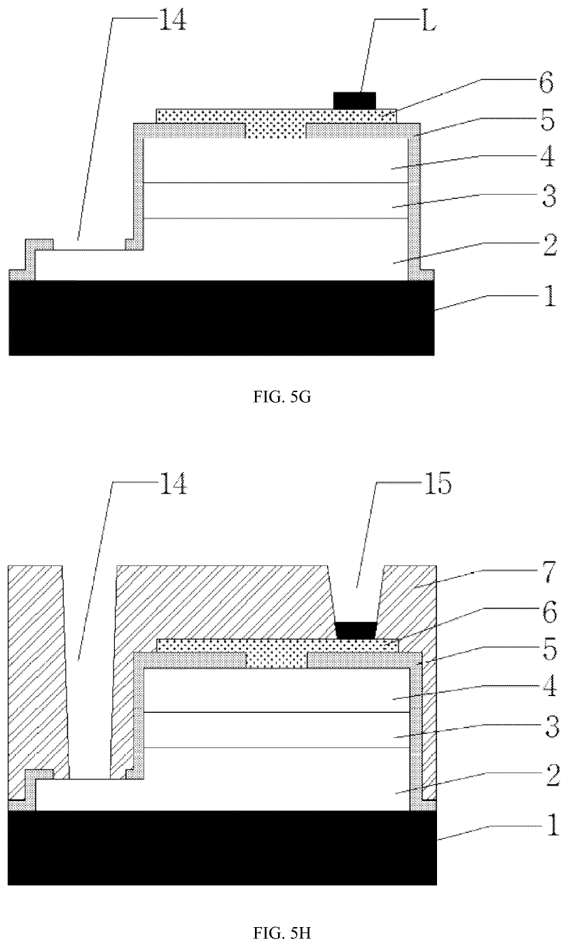

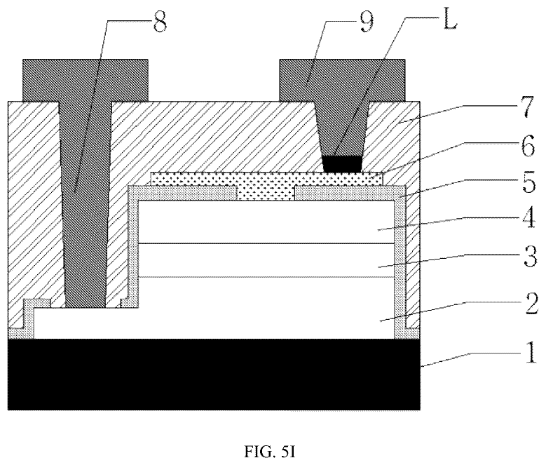

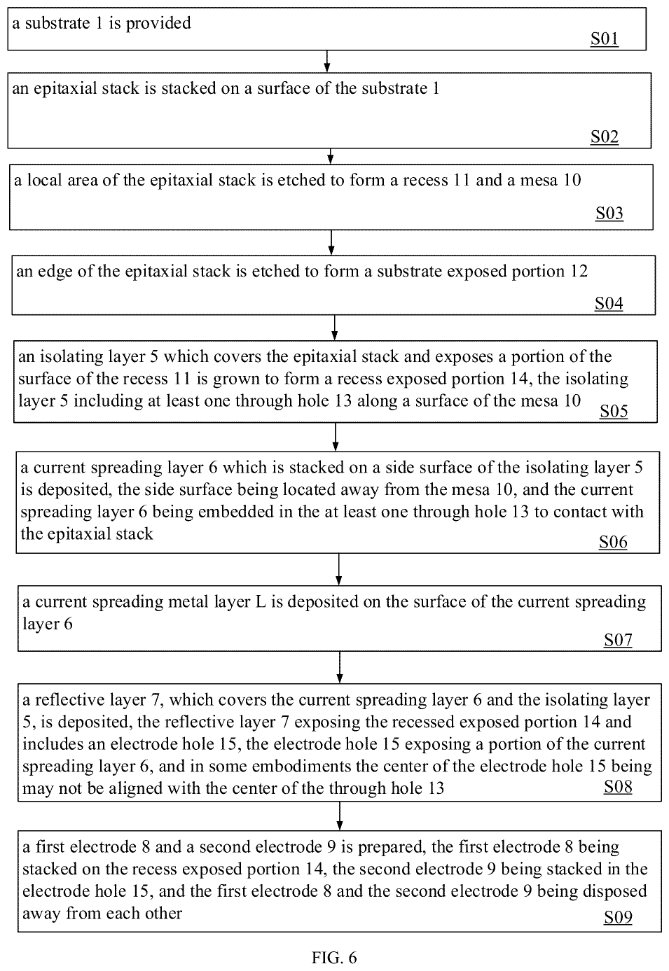

Some embodiments of the present disclosure provide a method for preparing an LED chip. As shown in FIG. 6, the preparation method includes the following steps:
Step S01, as shown in FIG. 5A, a substrate 1 is provided.
Step S02, as shown in FIG. 5B, an epitaxial stack is stacked on a surface of the substrate 1. In some embodiments, the epitaxial stack may include a first type semiconductor layer 2, an active layer 3, and a second type semiconductor layer 4. The first type semiconductor layer 2, the active layer 3, and the second type semiconductor layer 4 are sequentially stacked along a first direction. The first direction is perpendicular to the substrate 1, and points from the substrate 1 to the epitaxial stack. However, the detailed structure of the epitaxial stack is not limited to the embodiments of the present disclosure.
Step S03, as shown in FIG. 5C, a local area of the epitaxial stack is etched to form a recess 11 and a mesa 10.
Step S04, as shown in FIG. 5D, an edge of the epitaxial stack is etched to form a substrate exposed portion 12.
Step S05, as shown in FIG. 5E, an isolating layer 5 which covers the epitaxial stack and exposes a portion of the surface of the recess 11 is grown to form a recess exposed portion 14, the isolating layer 5 including at least one through hole 13 along a surface of the mesa 10.
Step S06, as shown in FIG. 5F, a current spreading layer 6 which is stacked on a side surface of the isolating layer 5 is deposited, the side surface being located away from the mesa 10, and the current spreading layer 6 being embedded in the at least one through hole 13 to contact with the epitaxial stack.
Step S07, as shown in FIG. 5G, a current spreading metal layer L is deposited on the surface of the current spreading layer 6.
Step S08, as shown in FIG. 5H, a reflective layer 7, which covers the current spreading layer 6 and the isolating layer 5, is deposited, the reflective layer 7 exposing the recessed exposed portion 14 and includes an electrode hole 15, the electrode hole 15 exposing a portion of the current spreading layer 6, and in some embodiments the center of the electrode hole 15 being may not be aligned with the center of the through hole 13.
Step S09, as shown in FIG. 5I, a first electrode 8 and a second electrode 9 is prepared, the first electrode 8 being stacked on the recess exposed portion 14, the second electrode 9 being stacked in the electrode hole 15, and the first electrode 8 and the second electrode 9 being disposed away from each other.

In some embodiments, depending on the requirements of the application scenario of the LED chip, the current spreading metal layer may not be necessarily deposited.

In another embodiment of the present disclosure, the total surface area of the at least one through hole 13 is S, and the area of a top surface of the mesa 10 is A, and S≥A/5. The total surface area of the at least one through hole is a sum of at least one projected area of the at least one through hole on the top surface of the mesa.

In another embodiment of the present disclosure, the method further includes etching the local area of the epitaxial stack to a part of the first type semiconductor layer 2 to form the recess 11 and the mesa 10.

In another embodiment of the present disclosure, the current spreading metal layer L is made of any one or any combination of chromium, nickel, aluminum, titanium, platinum, gold, palladium, silver, or a gold-tin alloy.

In another embodiment of the present disclosure, the current spreading layer 6 is made of any one or any combination of ITO, IZO, IGO, or ZnO.

In another embodiment of the present disclosure, the reflective layer 7 includes a DBR reflective layer 7.

In another embodiment of the present disclosure, the first electrode 8 or the second electrode 9 is made of any one or any combination of chromium, nickel, aluminum, titanium, platinum, gold, palladium, silver, or a gold-tin alloy.

As can be seen from the above technical solution, the LED chip includes an isolating layer 5, a current spreading layer 6, and a reflective layer 7. The isolating layer 5 covers the epitaxial stack and exposes a portion of the surface of the recess 11 to form a recess exposed portion 14, and the isolating layer 5 includes at least one through hole 13 along a surface of the mesa 10. The current spreading layer 6 is stacked on a side surface of the isolating layer 5; the side surface is located away from the mesa 10; the current spreading layer 6 is embedded in the at least one through hole 13 to contact with the epitaxial stack. The reflective layer 7 covers the current spreading layer 6 and the isolating layer 5; the reflective layer 7 exposes the recess exposed portion 14 and includes an electrode hole 15; the electrode hole exposes a portion of the current spreading layer 6, and the center of the electrode hole 15 is not aligned with the center of the at least one through hole 13. Thereby, control of the light-emitting area is realized through the at least one through hole 13; at the same time, the at least one through hole 13 is formed by an etching process of the isolating layer 5, and the isolating layer 5 is made of insulating materials, so that the etching process is easy to control, so as to better realize effective control of the light-emitting area.

Further, the LED chip provided by the present disclosure is provided with a current spreading metal layer on the surface of the current spreading layer. The electrode hole exposes the current spreading metal layer to form a connection between the second electrode and the current spreading metal layer so that the current spreading layer directly below the current spreading metal layer does not make direct contact with the second type semiconductor layer, so that currents are prevented from being collected directly below a spreading electrode, thereby improving the anti-ESD capability of the LED chip.

The LED chip preparation method provided by embodiments of the present disclosure not only achieves the beneficial effects of the above-mentioned LED chips, but also includes a simple and convenient manufacturing process and is convenient for production.

Each embodiment in this specification is described in a progressive manner. Each embodiment focuses on its differences from other embodiments. The same and similar parts between the various embodiments can be referred to each other.

Relational terms such as first and second are only used to distinguish one entity or operation from another entity or operation, and do not necessarily require or imply that these entities or operations There is no such actual relationship or sequence between them. Furthermore, the terms “comprises,” “comprises,” or any other variation thereof are intended to cover a non-exclusive inclusion, such that an article or device including a list of elements includes not only those elements, but also other elements not expressly listed, or it also includes elements inherent to the article or equipment. Without further limitation, elements qualified by the statement “comprises a . . . ” do not exclude the presence of other identical elements in articles or equipment containing the above-mentioned elements.

The above description of the disclosed embodiments enables those skilled in the art to make or use the present disclosure. The generic principles defined herein may be practiced in other embodiments without departing from the spirit or scope of the application. Therefore, the present disclosure is not to be limited to the embodiments shown herein but is to be accorded the widest scope consistent with the principles and novel features disclosed herein.

What is claimed is:

1. An LED chip, comprising:
a substrate;
an epitaxial stack, provided on a surface of the substrate, comprising a recess and a mesa;
an isolating layer, covering the epitaxial stack and exposing a portion of a surface of the recess to form a recess exposed portion, wherein the isolating layer comprises at least one through hole along a surface of the mesa;
a current spreading layer, stacked on a side surface of the isolating layer, wherein the side surface is located away from the mesa, and the current spreading layer is embedded in the at least one through hole to contact with the epitaxial stack;
a reflective layer, covering the current spreading layer and the isolating layer, wherein the reflective layer exposes the recess exposed portion and comprises an electrode hole, the electrode hole exposes a portion of the current spreading layer;
a first electrode, stacked on the recess exposed portion and extending upward to a surface of the reflective layer; and
a second electrode, stacked on the electrode hole and extending upward to the surface of the reflective layer.

2. The LED chip according to claim 1, wherein the epitaxial stack comprises a first type semiconductor layer, an active layer, and a second type semiconductor layer,
wherein the first type semiconductor layer, the active layer, and the second type semiconductor layer are sequentially stacked in a first direction, a local area of the epitaxial stack is etched to a part of the first type semiconductor layer, forming the recess and the mesa, and the first direction is perpendicular to the substrate, and points from the substrate to the epitaxial stack.

3. The LED chip according to claim 1, wherein a total surface area of the at least one through hole is S, an area of a top surface of the mesa is A, and S≥A/5;
wherein the total surface area of the at least one through hole is a sum of at least one projected area of the at least one through hole on the top surface of the mesa.

4. The LED chip according to claim 1, wherein the at least one through hole does not overlap with the electrode hole in orthogonal projections onto the mesa.

5. The LED chip according to claim 1, wherein the at least one through hole comprises a plurality of sub-through holes and a central through hole, wherein each of the plurality of sub-through holes is uniformly distributed around the central through hole.

6. The LED chip according to claim 1, further comprises:
a current spreading metal layer disposed on the current spreading layer,
wherein the electrode hole exposes the current spreading metal layer to form a connection between the second electrode and the current spreading metal layer.

7. The LED chip according to claim 6, the current spreading metal layer is made of any one or any combination of chromium, nickel, aluminum, titanium, platinum, gold, palladium, silver, or a gold-tin alloy.

8. The LED chip according to claim 1, wherein a center of the electrode hole is not aligned with a center of the at least one through hole.

9. The LED chip according to claim 1, wherein the reflective layer comprises a Distributed Bragg Reflector (DBR) reflective layer.

10. The LED chip according to claim 1, wherein the current spreading layer is made of any one or any combination of ITO, IZO, IGO, or ZnO, or
wherein the first electrode or the second electrode is made of any one or any combination of chromium, nickel, aluminum, titanium, platinum, gold, palladium, silver, or a gold-tin alloy.

11. The LED chip according to claim 1, wherein the epitaxial stack comprises at least one substrate exposed portion, the isolating layer and the reflective layer are stacked on the substrate by being retained on the at least one substrate exposed portion.

12. The LED chip according to claim 11, wherein the at least one substrate exposed portion surrounds a perimeter of the epitaxial stack, the isolating layer and the reflective layer are stacked on the substrate by being retained on the at least one substrate exposed portion and surrounding a perimeter of the epitaxial stack.

13. A LED chip preparation method comprising:
providing a substrate;
stacking an epitaxial stack on a surface of the substrate;
etching a local area of the epitaxial stack to form a recess and a mesa;
etching an edge of the epitaxial stack to form a substrate exposed portion;
growing an isolating layer which covers the epitaxial stack and exposes a portion of a surface of the recess to form a recess exposed portion, wherein the isolating layer comprises at least one through hole along a surface of the mesa;
depositing a current spreading layer which is stacked on a side surface of the isolating layer, wherein the side surface is located away from the mesa, and the current spreading layer is embedded in the at least one through hole to contact with the epitaxial stack;
depositing a reflective layer which covers the current spreading layer and the isolating layer, wherein the reflective layer exposes the recess exposed portion and comprises an electrode hole, the electrode hole exposes a portion of the current spreading layer; and
preparing a first electrode and a second electrode, wherein the first electrode is stacked on the recess exposed portion, the second electrode is stacked in the electrode hole, and the first electrode and the second electrode are disposed away from each other.

14. The LED chip preparation method according to claim 13, wherein a total surface area of the at least one through hole is S, an area of a top surface of the mesa is A, and S≥A/5;
wherein the total surface area of the at least one through hole is a sum of at least one projected area of the at least one through hole on the top surface of the mesa.

15. The LED chip preparation method according to claim 13, wherein the epitaxial stack comprises a first type semiconductor layer, an active layer, and a second type semiconductor layer; wherein the first type semiconductor layer, the active layer, and the second type semiconductor layer are sequentially stacked in a first direction; wherein the first direction is perpendicular to the substrate, and points from the substrate to the epitaxial stack;
wherein etching the local area of the epitaxial stack to form the recess and the mesa comprises:
etching the local area of the epitaxial stack to a part of the first type semiconductor layer to form the recess and the mesa.

16. The LED chip preparation method according to claim 13, further comprising:
depositing a current spreading metal layer on a surface of the current spreading layer.

17. The LED chip preparation method according to claim 13, the current spreading metal layer is made of any one or any combination of chromium, nickel, aluminum, titanium, platinum, gold, palladium, silver, or a gold-tin alloy.

18. The LED chip preparation method according to claim 13, wherein a center of the electrode hole is not aligned with a center of the at least one through hole.

19. The LED chip preparation method according to claim 13, wherein the reflective layer comprises a DBR reflective layer.

20. The LED chip preparation method according to claim 13, wherein the current spreading layer is made of any one or any combination of ITO, IZO, IGO, or ZnO, or
wherein the first electrode or the second electrode is made of any one or any combination of chromium, nickel, aluminum, titanium, platinum, gold, palladium, silver, or a gold-tin alloy.
